(19) United States
(12) Patent Application Publication
(10) Pub. No.: US 2008/0224232 A1
(43) Pub. Date: Sep. 18, 2008

(54) SILICIDATION PROCESS FOR MOS TRANSISTOR AND TRANSISTOR STRUCTURE

(75) Inventors: Chao-Ching Hsieh, Hsinchu County (TW); Yu-Lan Chang, Kaohsiung City (TW); Chien-Chung Huang, Taichung Hsien (TW); Tzung-Yu Hung, Tainan County (TW); Chun-Chieh Chang, Tainan County (TW); Yi-Wei Chen, Taichung County (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/687,185

(22) Filed: Mar. 16, 2007

(51) Int. Cl. H01L 29/78; H01L 21/336

(52) U.S. Cl. 257/384; 438/682; 438/768; 438/299; 257/412

(57) ABSTRACT

A silicidation process for a MOS transistor and a resulting transistor structure are described. The MOS transistor includes a silicon substrate, a gate dielectric layer, a silicon gate, a cap layer on the silicon gate, a spacer on the sidewalls of the silicon gate and the cap layer, and S/D regions in the substrate beside the silicon gate. The process includes forming a metal silicide layer on the S/D regions, utilizing plasma of a reactive gas to react a surface layer of the metal silicide layer into a passivation layer, removing the cap layer and then reacting the silicon gate into a fully silicided gate.

### BACKGROUND OF THE INVENTION

1. Field of the Invention

This invention relates to a semiconductor process and a semiconductor device structure. More particularly, this invention relates to a silicidation process for a MOS transistor and a resulting transistor structure.

2. Description of Related Art

In recent years, a self-aligned silicide (salicide) process is usually included in a MOS transistor process to reduce the resistance of the S/D regions and silicon gates. A conventional salicide process includes forming a layer of refractory metal on a transistor, thermally reacting the silicon material at the surfaces of S/D regions and gates with the metal to form a metal silicide layer and then removing the unreacted metal.

However, as the dimension of the semiconductor device is further reduced, the resistance of the gate has to be further lowered. One way to lower the resistance is to react the entire silicon gate into a metal silicide. However, because the depth of the S/D regions is smaller than the thickness of the silicon gate, the silicon material of the S/D regions would be completely exhausted when the entire silicon gate is reacted into a metal silicide in a conventional salicide process, thus causing short circuits.

To solve the above problem, several full silicidation (FUSI) processes have been disclosed in prior art. One method includes forming a thin silicon gate with a thick cap layer disposed thereon serving as an ion-implantation mask for S/D regions. After the S/D regions are formed, the cap layer is removed. A salicide process is then performed to form metal silicide on the S/D regions and simultaneously form a fully silicided gate. However, when the metal used is nickel, the above process is not easy to control.

Another method includes forming a silicon gate with a normal thickness that has a cap layer disposed thereon and a spacer disposed on its sidewall. After a salicide is formed on the S/D regions, a dielectric layer is deposited on a substrate, and then chemical mechanical polishing (CMP) is performed to remove a portion of the dielectric layer to expose the cap layer. After the cap layer is removed, another salicide process is performed to react the silicon gate into a fully silicided gate, wherein the salicide on the S/D regions is not affected as being isolated by the dielectric layer. However, the CMP process is quite tedious and is difficult to control.

### SUMMARY OF THE INVENTION

Accordingly, this invention provides a silicidation process for an MOS transistor, which is simple and is easy to control.

This invention further provides a transistor structure, which results from the above silicidation process for an MOS transistor of this invention.

In the silicidation process for an MOS transistor of this invention, the MOS transistor includes a silicon substrate, a gate dielectric layer on the silicon substrate, a silicon gate on the gate dielectric layer, a cap layer on the silicon gate, a spacer on the sidewalls of the silicon gate and the cap layer, and S/D regions in the substrate beside the silicon gate. The silicidation process includes forming a metal silicide layer on the S/D regions, utilizing plasma of a reactive gas to react a surface layer of the metal silicide layer into a passivation layer, removing the cap layer and then reacting the silicon gate into a fully silicided gate.

The reactive gas includes, for example, a nitrogen-containing gas, a oxygen-containing gas or a gas containing nitrogen and oxygen, wherein the nitrogen-containing gas may be N₂ or NH₃, the oxygen-containing gas may be O₂ or O₃, and the gas containing nitrogen and oxygen may be N₂O or NO.

The material of the cap layer is, for example, silicon nitride, silicon oxide or silicon oxynitride. When the material of the cap layer is silicon oxide, the reactive gas may include a nitrogen-containing gas or a gas containing nitrogen and oxygen, and the cap layer may be removed with hydrofluoric acid (HF). When the material of the cap layer is silicon nitride or silicon oxynitride, the reactive gas may include an oxygen-containing gas.

The transistor structure of this invention includes a silicon substrate, a gate dielectric layer on the silicon substrate, a fully silicided gate on the gate dielectric layer, a spacer on the sidewall of the fully silicided gate, S/D regions in the substrate beside the fully silicided gate, a metal silicide layer on the S/D regions, and a passivation layer covering the metal silicide layer. The passivation layer is formed from a reaction of the material of the metal silicide layer.

The material of the passivation layer is, for example, silicon nitride, silicon oxide, silicon oxynitride, or a nitride, oxide or oxynitride of an alloy of silicon with one or two metals.

Further, the material of the spacer is, for example, silicon nitride, silicon oxide or silicon oxynitride. When the material of the spacer is silicon nitride or silicon oxynitride, the material of the passivation layer may be silicon nitride, silicon oxynitride, or a nitride or oxynitride of an alloy of silicon with one or two metals. When the material of the spacer is silicon oxide, the material of the passivation layer may be silicon oxide or an oxide of an alloy of silicon with one or two metals.

Moreover, the material of the metal silicide layer is, for example, a silicide of Ni, Co, Ti, Cu, Mo, Ta, W, Er, Zr, Pt, Yb, Gd, Dy or an alloy of any two thereof, and is preferably nickel platinum silicide. The material of the fully silicided gate is, for example, a silicide of Ni, Co, Ti, Cu, Mo, Ta, W, Er, Zr, Pt, Yb, Gd or Dy, which can be a silicon-rich, stoichiometric or metal-rich metal silicide.

Different from the prior art of depositing a dielectric layer and then performing CMP to form a passivation layer, this invention utilizes plasma to form a passivation layer on the S/D metal silicide layer, so that the process of this invention is simple and is easy to control.

It is to be understood that both the foregoing general description and the following detailed description are exemplary, and are intended to provide further explanation of the invention as claimed.

### BRIEF DESCRIPTION OF THE DRAWINGS

FIGS. 1-3 illustrate, in a cross-sectional view, a flow of a silicidation process for an MOS transistor according to a preferred embodiment of this invention, wherein FIG. 3 also shows a transistor structure according to the preferred embodiment.

### DESCRIPTION OF EMBODIMENTS

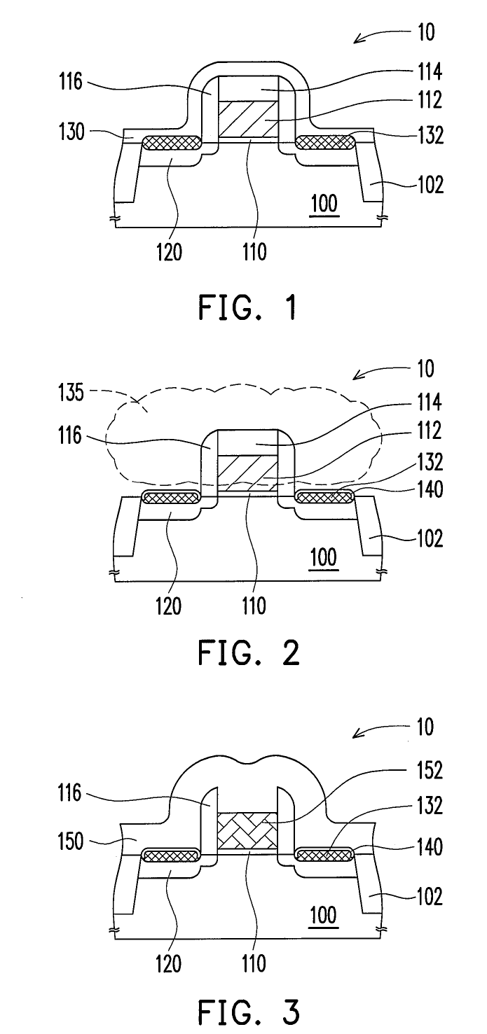

FIGS. 1-3 illustrate, in a cross-sectional view, a flow of the silicidation process for an MOS transistor according to a preferred embodiment of this invention.

Referring to FIG. 1, an MOS transistor 10 is provided, which includes a silicon substrate 100 formed with an isolation layer 102 therein, a gate dielectric layer 110 on the silicon substrate 100, a silicon gate 112 on the gate dielectric layer 110, a cap layer 114 on the silicon gate 112, a spacer 116 on the sidewalls of the silicon gate 112 and the cap layer 114, and S/D regions 120 in the substrate 100 beside the silicon gate 112. The silicon substrate 100 is, for example, a lightly P-doped or lightly N-doped silicon substrate, the gate dielectric layer 110 may be a gate oxide layer, and the material of the silicon gate 112 may be polysilicon.

In addition, the cap layer 114 may be a hard mask layer for defining the silicon gate 112 in a preceding process. The material of the cap layer 114 and that of the spacer 116 preferably have a high etching selectivity therebetween to prevent the spacer 116 from being damaged in the subsequent removal of the cap layer 114. For example, it is feasible that the material of the cap layer 114 is silicon nitride or silicon oxynitride and that of the spacer 116 is silicon oxide, or the material of the former is silicon oxide and that of the latter is silicon nitride or silicon oxynitride, for silicon oxide and silicon nitride (oxynitride) have a high etching selectivity therebetween. Moreover, when the silicon substrate 100 is a lightly P-doped (or lightly N-doped) silicon substrate, the S/D regions 120 are N-type (or P-type) doped regions. The dopant in N-type doped regions is usually phosphorous or arsenic, and that in P-type doped regions is usually boron.

Referring to FIG. 1, a first salicide process is performed as illustrated. First, a refractory metal layer 130 is deposited above the substrate 100, the material thereof being, for example, nickel (Ni), cobalt (Co), titanium (Ti), copper (Cu), molybdenum (Mo), tantalum (Ta), tungsten (W), erbium (Er), zirconium (Zr), platinum (Pt), ytterbium (Yb), gadolinium (Gd), dysprosium (Dy) or an alloy of any two thereof, and preferably being a Ni—Pt alloy because nickel platinum silicide has high thermostability. The deposition method may be a sputtering method, which is implemented with a target composed of one of the above metal elements or an alloy of any two of the same.

Afterwards, an annealing step is performed to react the surface silicon material of the S/D regions 120 with the refractory metal layer 130 to form a metal silicide layer 132, whose material is a silicide of one of the above metal elements or a silicide of an alloy of any two of the same. The temperature and duration for the annealing depend on the material of the refractory metal layer 130 and the predetermined thickness of the metal silicide layer 132. For example, when the material of the refractory metal layer 130 is an Ni—Pt alloy, the annealing temperature preferably ranges from 250° C. to 450° C., and the duration usually does not exceed 5 min. In some embodiments, the annealing step may be a spike annealing step. In the above annealing step, no metal silicide is formed on the silicon gate 112 under the protection of the cap layer 114.

Referring to FIG. 2, the unreacted metal is removed after the metal silicide layer 132 is formed. Some metal silicides like titanium silicide, cobalt silicide and nickel silicide are preferably subjected to another annealing step after the unreacted metal is removed, so as to be converted to a phase of low resistance. Next, plasma 135 of a reactive gas is used to react a surface layer of the metal silicide layer 132 into a passivation layer 140, wherein the material of the passivation layer 140 and the material of the cap layer 114 should have a high etching selectivity therebetween to avoid the passivation layer 140 from being damaged during the subsequent removal of the cap layer 114. The thickness of the passivation layer 140 is preferably larger than 50 Å, so as to effectively isolate the metal silicide layer 132 from the later-formed refractory metal layer 150 (see FIG. 3) for metallizing the silicon gate 112 during the subsequent FUSI process for the silicon gate 112 as well as from the solution for removing the cap layer 114. Moreover, because the reactivity of the metal silicide layer 132 is much higher than that of the cap layer 114 which is generally an insulator, by carefully controlling the plasma treatment condition, the surface material of the cap layer 114 will not be changed lowering the etching selectivity between the cap layer 114 and the passivation layer 140.

The above reactive gas includes, for example, a nitrogen-containing gas, an oxygen-containing gas, or a gas containing nitrogen and oxygen. The nitrogen-containing gas may be N₂ or NH₃, the oxygen-containing gas may be O₂ or O₃, and the gas containing nitrogen and oxygen may be N₂O or NO. For example, when the above reactive gas is NH₃, the flow rate thereof can be 200-3000 sccm, the power can be 500-3000 W. and the processing temperature can be 350-500° C. When the above reactive gas is N₂O, the flow rate thereof can be 200-3000 sccm, the power can be 500-3000 W, and the processing temperature can be 350-500° C. When the above reactive gas is O₂, the flow rate thereof can be 200-3000 sccm, the power can be 500-3000 W, and the processing temperature can be 350-500° C.

When the material of the cap layer 114 is silicon oxide and that of the spacer 116 is silicon nitride or silicon oxynitride, the above reactive gas may include a nitrogen-containing gas or a gas containing nitrogen and oxygen, so as to form a passivation layer 140 of silicon nitride, silicon oxynitride, a nitride of an alloy of silicon with one or two metals, or a oxynitride of an alloy of silicon with one or two metals. When the material of the cap layer 114 is silicon nitride or silicon oxynitride and that of the spacer 116 is silicon oxide, the above reactive gas may include an oxygen-containing gas, so as to form a passivation layer 140 of silicon oxide or an oxide of an alloy of silicon with one or two metals. Because silicon nitride (oxynitride) and silicon oxide have a high etching selectivity therebetween, in such cases, the passivation layer 140 is not damaged during the subsequent removal of the cap layer 114. Further, whether the passivation layer 140 contains one or two metals in the metal silicide layer 132 or not depends on the material of the metal silicide layer 132 and the conditions of the plasma treatment.

Referring to FIG. 3, the cap layer 114 is then removed. When the material of the cap layer 114 is silicon oxide, the cap layer 114 can be removed with hydrofluoric acid (HF) possibly in a concentration of 1 wt %. Then, a second salicide process is performed as follows.

First, a refractory metal layer 150 is deposited above the substrate 100, the material thereof being, for example, Ni, Co, Ti, Cu, Mo, Ta, W, Er, Zr, Pt, Yb, Gd or Dy. Afterwards, an annealing step is performed to react the refractory metal layer 150 with all silicon material of the silicon gate 112 to form a fully silicided gate 152 whose material is a silicide of one of the above metal elements. The silicide may be a silicon-rich metal silicide, a stoichiometric metal silicide or a metal-rich metal silicide, depending on the species of the metal element and the annealing condition.

For example, when the material of the refractory metal layer 150 is nickel, a silicon-rich metal silicide, such as NiSi₂ or NiSi, or a metal-rich metal silicide, such as Ni₂Si, Ni₃₁Si₁₂ or Ni₃Si, can be formed by adjusting the annealing condition. For example, in order to form a fully silicided gate 152 of NiSi₂, the annealing temperature is preferably between 400° C. and 700° C.

During the above second salicide process, the metal silicide layer 132 on the S/D regions 120 is not affected by the refractory metal layer 150 due to the protection of the passivation layer 140 disposed thereon.

Referring to FIG. 3, the unreacted metal is removed after the fully silicided gate 152 is formed, thus forming a transistor structure according to a preferred embodiment of this invention, which features that the metal silicide layer 132 on the S/D regions 120 is covered by a passivation layer 140 that is formed from a reaction of the material of the metal silicide layer 132.

Because the passivation layer on the S/D metal silicide layer in this invention is formed with plasma treatment, instead of deposition of a dielectric layer and subsequent CMP as in the prior art, the process of this invention is simple and is easy to control.

Though this invention has been disclosed above by the preferred embodiments, they are not intended to limit this invention. Anybody skilled in the art can make some modifications and variations without departing from the spirit and scope of this invention. Therefore, the protecting range of this invention falls in the appended claims.

What is claimed is:

1. A silicidation process for a metal oxide semiconductor (MOS) transistor, wherein the MOS transistor comprises a silicon substrate, a gate dielectric layer on the silicon substrate, a silicon gate on the gate dielectric layer, a cap layer on the silicon gate, a spacer on sidewalls of the silicon gate and the cap layer, and source/drain (S/D) regions in the substrate beside the silicon gate, the process comprising:
forming a metal silicide layer on the S/D regions;
utilizing plasma of a reactive gas to react a surface layer of the metal silicide layer into a passivation layer;
removing the cap layer; and
reacting the silicon gate into a fully silicided gate.

2. The silicidation process of claim 1, wherein the reactive gas comprises a nitrogen-containing gas, an oxygen-containing gas, or a gas containing nitrogen and oxygen.

3. The silicidation process of claim 2, wherein the nitrogen-containing gas is N₂ or NH₃.

4. The silicidation process of claim 2, wherein the oxygen-containing gas is O₂ or O₃.

5. The silicidation process of claim 2, wherein the gas containing nitrogen and oxygen is N₂O or NO.

6. The silicidation process of claim 1, wherein a material of the cap layer is silicon nitride, silicon oxide or silicon oxynitride.

7. The silicidation process of claim 6, wherein the material of the cap layer is silicon nitride or silicon oxynitride, and the reactive gas comprises an oxygen-containing gas.

8. The silicidation process of claim 6, wherein the material of the cap layer is silicon oxide, and the reactive gas comprises a nitrogen-containing gas or a gas containing nitrogen and oxygen.

9. The silicidation process of claim 8, wherein the cap layer is removed with hydrofluoric acid.

10. The silicidation process of claim 1, wherein a material of the metal silicide layer is a silicide of Ni, Co, Ti, Cu, Mo, Ta, W, Er, Zr, Pt, Yb, Gd, Dy or an alloy of any two thereof.

11. The silicidation process of claim 10, wherein the material of the metal silicide layer is nickel platinum silicide.

12. The silicidation process of claim 1, wherein a material of the fully silicided gate is a silicide of Ni, Co, Ti, Cu, Mo, Ta, W, Er, Zr, Pt, Yb, Gd or Dy.

13. The silicidation process of claim 12, wherein the silicide is a silicon-rich metal silicide, a stoichiometric metal silicide or a metal-rich metal silicide.

14. A transistor structure, comprising:
a silicon substrate;
a gate dielectric layer on the silicon substrate;
a fully silicided gate on the gate dielectric layer;
a spacer on a sidewall of the fully silicided gate;
S/D regions in the substrate beside the fully silicided gate;
a metal silicide layer on the S/D regions; and
a passivation layer covering the metal silicide layer, being formed from a reaction of a material of the metal silicide layer.

15. The transistor structure of claim 14, wherein a material of the passivation layer is silicon nitride, silicon oxide, silicon oxynitride, a nitride of an alloy of silicon with one or two metals, an oxide of an alloy of silicon with one or two metals, or an oxynitride of an alloy of silicon with one or two metals.

16. The transistor structure of claim 14, wherein a material of the spacer is silicon nitride, silicon oxide or silicon oxynitride.

17. The transistor structure of claim 16, wherein the material of the spacer is silicon nitride or silicon oxynitride, and a material of the passivation layer is silicon nitride, silicon oxynitride, a nitride of an alloy of silicon with one or two metals, or an oxynitride of an alloy of silicon with one or two metals.

18. The transistor structure of claim 16, wherein the material of the spacer is silicon oxide, and a material of the passivation layer is silicon oxide, or an oxide of an alloy of silicon with one or two metals.

19. The transistor structure of claim 14, wherein a material of the metal silicide layer is a silicide of Ni, Co, Ti, Cu, Mo, Ta, W. Er, Zr, Pt, Yb, Gd, Dy or an alloy of any two thereof.

20. The transistor structure of claim 19, wherein the material of the metal silicide layer is nickel platinum silicide.

21. The transistor structure of claim 14, wherein a material of the fully silicided gate is a silicide of Ni, Co, Ti, Cu, Mo, Ta, W. Er, Zr, Pt, Yb, Gd or Dy.

22. The transistor structure of claim 21, wherein the silicide is a silicon-rich metal silicide, a stoichiometric metal silicide or a metal-rich metal silicide.
